(19) United States
(12) Patent Application Publication
(10) Pub. No.: US 2006/0086518 A1
(43) Pub. Date: Apr. 27, 2006

(54) Shield box and shield method

(76) Inventors: Toshiyuki Kawaguchi, Tokyo (JP); Katsuhiko Seriguchi, Kawaguchi-shi (JP); Hiroto Komatsu, Saitama-shi (JP); Kiyofumi Tanaka, Kita-adachi-gun (JP); Hiroshi Kato, Kounosu-shi (JP)

Correspondence Address: OSTROLENK FABER GERB & SOFFEN, 1180 AVENUE OF THE AMERICAS, NEW YORK, NY, 100368403, US

(21) Appl. No.: 10/536,870

(22) PCT Filed: Feb. 13, 2004
(86) PCT No.: PCT/JP04/01582

§ 371 Date: May 27, 2005

(30) Foreign Application Priority Data
Mar. 31, 2003 (JP) 2003-096872

(51) Int. Cl. H05K 9/00

(52) U.S. Cl. 174/35 R

(57) ABSTRACT

This shielding box comprises a molded body formed like a box having a bottom wall, side walls formed to rise from the outer peripheries of the bottom wall, and an opening described by the edges of the side walls opposite the bottom wall. The side walls are connected to the bottom wall through elastic connectors formed to act as plate springs with respect to the bottom wall, and at least one of the inner surface and outer surface of the molded body is electrically conductive.

### TECHNICAL FIELD

The present invention relates to a shielding box and a shielding method for protecting electronic circuits comprising electronic components such as ICs mounted on a wiring board from external electromagnetic waves or for preventing the leakage of electromagnetic waves from the electronic components.

### BACKGROUND ART

In electronic devices such as mobile telephones and portable radios, electronic circuits such as high-frequency circuits, logic circuits, transmitting circuits and receiving circuits comprising electronic components such as ICs and LSIs mounted on a wiring board require electromagnetic wave shielding to prevent malfunction caused by external electromagnetic noise or to ensure that electromagnetic wave leakage from the electronic circuits does not affect other devices or the human body.

A known method for shielding electromagnetic waves is to enclose the electronic circuits with the ground of the wiring board and a shielding box that is an electrically conductive case.

Since the shielding box should be easily removable for maintenance of the enclosed electronics and have good assemblability, ingenuity is required in connecting the shielding box to the ground of the wiring board.

As an attempt to increase the mounting capacity of electronic components and achieve further miniaturization in small electronic devices, it has been proposed to directly connect the junction surface of a shielding box to the ground of the wiring board by attaching a resin case with a metal plate formed integrally therein or a shielding box having the same rigidity as the wiring board using engaging hooks or screws (for example, refer to Japanese Unexamined Patent Application, First Publication No. 2000-151132).

As a measure against electromagnetic wave leakage stemming from gaps between the shielding box and the wiring board caused by warping of the substrate and insufficient dimensional precision in molding the shielding box and the like, it has also been proposed to connect a shielding box made of metal or plated resin to the ground of the wiring board via a small springy metallic piece (for example, refer to Japanese Unexamined Patent Application, First Publication No. H10-224074).

It is also proposed to install plastically deformable, small projections whose surfaces are made electrically conductive on the wall of an injection-molded resin shielding box, apply conductivity treatment by nickel or copper plating or vacuum deposition and sputtering, and then connect the shielding case to the ground of the wiring board via the small projections (for example, refer to Japanese Unexamined Patent Application, First Publication No. H10-22671).

It is also proposed to make a connection by mounting conductive rubber on the junction surface of the shielding box with the ground of the wiring board, wherein the shielding box is made of resin containing powdered metal or is formed in a case to which an electrically conductive paint is applied (for example, refer to Japanese Unexamined Patent Application, First Publication No. 2000-196278 and Japanese Unexamined Patent Application, First Publication No. 2001-111283).

There is still a further proposal for making the connection with the connection face of the ground of the wiring board by providing a flap at the end of a side wall of a resin shielding box which is made electrically conductive by treatment with conductive paint, electroless plating, sputtering or ion plating (for example, refer to Japanese Patent No. 3283161).

Various researches have been carried out on a method for conductivity treatment of a shielding box made of plastic. As an attempt to make a plastic molding such as a shielding box electrically conductive, there is a proposal for an improvement to nonelectrolytic plating of a plastic material as a replacement for applying a metal spray or conductive paint, use of a resin containing a conductive filler, metal deposition, sputtering and ion plating (for example, refer to Japanese Examined Patent Application, Second Publication No. H05-9959).

Also proposed is an ion plating method in which a film is applied by evaporating copper or aluminum using such means as resistance heating and then ionizing the metal with a high-frequency excitation plasma (for example, refer to Japanese Unexamined Patent Application, First Publication No. H07-7283).

However, Japanese Unexamined Patent Application, First Publication No. 2000-151132 has the problems of strain and warping easily occurring in the case, shielding box or printed wiring board, giving rise to fears of gaps occurring between the junction surface of the shielding box and the ground of the wiring board, thereby leading to a loss of sufficient shielding performance. Using stress to have a rigid case follow the contours of its connection counterpart, i.e., form a connection, entails considerable stress, thereby requiring the area surrounding the engaging hooks or screws to be rigid. This gives rise to a problem of excess volume and weight in electronic devices such as mobile telephones and portable radios.

In Japanese Unexamined Patent Application, First Publication No. H10-224074, a small springy metallic piece must be soldered in advance to the wiring board, which is time consuming, and any deformation of the piece from handling during this process must be corrected, leading to low productivity. In addition, the large number of components make it impractical, and in recycling, separation and selection of components are not easy.

Japanese Published Unexamined Patent Application, First Publication No. H10-22671 discloses making the shielding box conductive by physical deposition. However, the connection between the shielding box and the wiring board is achieved by using electrically conductive small projections. These small projections are made of the same material as that of the shielding box and, thus, during connection stress is concentrated on the tips of the conductive small projections, causing them to easily undergo plastic deformation. Once deformed plastically, the projections should be repaired, which involves opening the shielding box and then reassembling. However, doing so impairs electrical conduction, which is a defect. In other words, the electrically conductive small projections have the defect in which they easily experience plastic deformation when subjected to a force above a predetermined threshold, and once plastically deformed, the shielding box must be reopened for repair and then reassembled, leading to electrical conduction becoming uncertain.

In Japanese Unexamined Patent Application, First Publication No. 2000-196278, the shielding box is prepared by molding a resin in which is blended a powdered stainless steel. However, such resin lacks reliability due to difficulties in obtaining a uniform dispersion and conductivity greatly varying according to location. The shielding box made conductive by this method has rigidity, and the junction surface of the shielding box with the ground of the wiring board, in other words, the width in a portion of the external wall or rib of the shielding box, is as narrow as 1 mm or less. Fitting conductive members there is therefore very difficult, resulting in cutting-off or stretching of elastic members, which takes time and causes a loss of productivity.

In the case where a liquid material is provided by a dispenser and the like as in Japanese Unexamined Patent Application, First Publication No. 2001-111283, an expensive apparatus must be used having positional controlling and discharge regulating functions. In addition, after the case or the shielding box is manufactured, its must be conveyed to the place where dispensing processing can be performed. This leads to longer production times and damage to the cases, resulting in the disadvantage of a low passing ratio.

The shielding boxes disclosed in Japanese Unexamined Patent Application, First Publication No. H10-22671, Japanese Unexamined Patent Application, First Publication No. 2000-196278, and Japanese Unexamined Patent Application, First Publication No. 2001-111283 are fitted to the wiring board by using screws or engagement parts that pass through holes opened in the wiring board. But this has the problem of opening and reassembly of the shielding box during repair and the like being troublesome.

The specification of Japanese Patent No. 3283161 discloses a flap portion provided on the shielding box for connection to the ground of the wiring board. However, the height of this flap portion is insufficient with regard to the compressive displacement, so that when the elasticity limit is exceeded during assembly, plastic deformation results that cannot be reversed. There is also the problem in which, before the flap deforms, the side wall portion, which has less strength than that of the flap portion, buckles. An attempt to utilize the elasticity of the flap portion leads to an increase in the diameter of the folded back portion, that is, the side wall, which requires that the width of the ground of the wiring board to be connected is increased. This poses problems disadvantageous to miniaturization. The thickness of the conductive layer made by conductivity treatment reaches 1 to 3 μm, thereby inhibiting elasticity of the flap. Therefore, compressive deformation of a composite layer having a different flexibility gives rise to the problems of cracking and peeling of the conductive layer, which causes failure of the ground connection, and shorting of the housed electronic components by pieces of the peeled off conductive layer.

Japanese Examined Patent Application, Second Publication No. H05-9959 discloses providing a metal film having a thickness of at least 1.5 μm by applying conductivity treatment to the case itself of the electronic device. But this neither simply nor surely shields the concerned electronic components in electronic devices such as mobile telephones and portables radios from electromagnetic waves.

Japanese Unexamined Patent Application, First Publication No. H07-7283 discloses a method for applying electrical conductivity treatment. However, this conductivity treatment is for the case itself of the electronic device and, same as described above, not for a convenient connection mechanism between the shielding box and the wiring board.

Thus, the conventional shielding structures described above have problems concerning a limit to the shielding performance provided to small electronic devices such as mobile telephones and assemblability in a short time stemming from their difficult assembly. In addition, the number of components increases and a robust case must be manufactured, thereby sacrificing the smallness and lightness of electronic devices. Moreover, a special device and a conveyance time are required, impacting efficiency.

### DISCLOSURE OF INVENTION

In view of the above circumstances, it is the object of the present invention to provide a shielding box and a shielding method that conveniently and surely effect electromagnetic wave shielding with a shielding box.

The shielding box according to the present invention includes a molded body formed like a box having a bottom wall, side walls formed to rise from the outer peripheries of the bottom wall, and an opening described by the edges of the side walls opposite the bottom wall, the side walls being connected to the bottom wall through elastic connectors formed to act as plate springs with respect to the bottom wall, and at least one of the inner surface and outer surface of the molded body being electrically conductive.

The shielding box of the present invention for blocking electromagnetic waves is housed in a case and covers electronic circuits on a wiring board, the shielding box comprising a molded body formed like a box having a bottom wall, side walls formed to rise from the outer peripheries of the bottom wall, and an opening described by the edges of the side walls opposite the bottom wall; at least one of the inner surface and outer surface of the molded body having a metal thin film formed by physical deposition; and the ends of the side walls at the opening side making contact with the wiring board while a portion of the shielding box being pressed by an inner wall of the case elastically deforms when securing the shielding box and the wiring board.

The shielding box has partition walls dividing its interior into a plurality of cells, the partition walls may be connected to the bottom wall through elastic connectors formed to act as plate springs with respect to the bottom wall.

The shear modulus of elasticity of the material constituting the molded body may range from 10⁵ to 10⁹ Pa.

The elastic connectors may include a rising portion that rises once from the bottom wall toward the opening and a horizontal portion that extends in parallel to the bottom wall, connecting the end of the rising portion opposite the bottom wall and the opposite end of the side wall or the partition wall.

When the distance of the horizontal portions of the elastic connectors is H and the height of the rising portions is V, it may be that H≧V.

The thickness of the side walls and/or the partition walls may be 1 mm or less.

The surface resistance of at least one of the inner surface and the outer surface of the molded body may range from 10¹ to 10⁻² Ω/□.

The partition walls may be divided into a plurality of pieces by slits.

The molded body may be formed by molded body from one sheet of material.

The free height of the shielding box may be larger than the gap formed between the inner surface of the case and the wiring board facing each other, the gap being in the space surrounded by the case in which the shielding box is housed and the wiring board.

The side walls may be connected to the bottom wall through elastic connectors formed to function as plate springs with respect to the bottom wall.

The metal thin film from physical deposition may be formed by using a facing target-type sputtering apparatus.

The surface resistance of at least one of the inner surface and the outer surface of the molded body may range from 10¹ to 10⁻² Ω/□, and the relationship between the thickness T (nm) and the surface resistance R (Ω/□) of the metal thin film may satisfy the condition T×R<200 in a range of 20<T<200.

The metal thin film may be made from a plurality of metals.

The metal thin film may be a brass thin film.

The shielding method according to the present invention effects electromagnetic wave shielding by housing the shielding box in a case having a wiring board stored therein, pressing the bottom wall of the shielding box by the inner surface of the case opposing the wiring board so as to press the ends of the side walls and/or partition walls against the wiring board while elastically deforming the elastic connectors, and covering the electronic circuits on the wiring board with the shielding box.

### BRIEF DESCRIPTION OF THE DRAWINGS

FIG. 1 is an exploded perspective view of an electronic device incorporating the shielding box.

FIG. 2 is a perspective view of the shielding box in the state of the bottom wall facing up.

FIG. 3 is a perspective view of the shielding box in the state of the opening facing up.

FIG. 4 is a sectional view showing an embodiment of the shielding box of the present invention.

FIG. 5 is a main sectional view showing the states before and after pressing the bottom walls of an embodiment of the shielding box of the present invention.

FIGS. 6 to 9 are sectional views showing other embodiments of the shielding box of the present invention.

FIGS. 10 and 11 are perspective views showing still other embodiments of the shielding box of the present invention.

### BEST MODE FOR CARRYING OUT THE INVENTION

Referring to the drawings, preferred embodiments of the present invention are explained herewith. The present invention is not considered as being restricted to the following embodiments, with various combinations of individual constitutional elements of these embodiments being allowed.

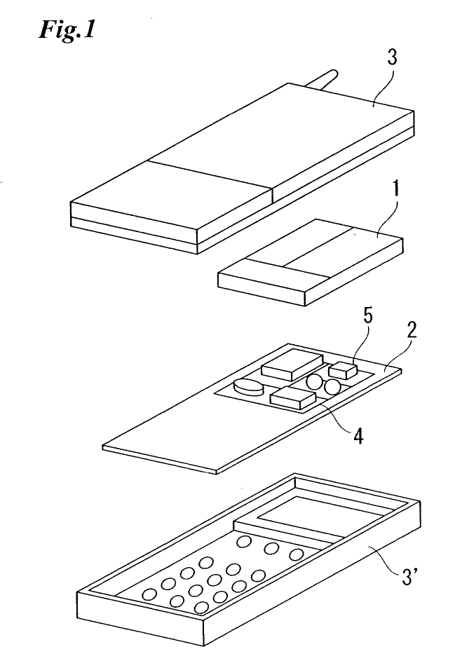

FIG. 1 is an exploded perspective view of an electronic device incorporating the shielding box. Shielding box 1 and wiring board 2 are, as shown in FIG. 1, arranged between divided case 3 and 3′ of the electronic device. The shielding box 1 and a metal foil (not shown) in a separate layer of the wiring board 2 surround various electronic circuits 5 on the wiring board 2. The shielding box 1 is used by connecting it to ground 4 on the wiring board having the same electric potential as that of the metal foil. Electronic circuits 5 include such functions as high-frequency circuits, logic circuits, transmitting circuits and receiving circuits. The individual circuits are partitioned by ground 4 because their respective degree of influence by external electromagnetic noise or the frequency and intensity of their leaked electromagnetic waves differ.

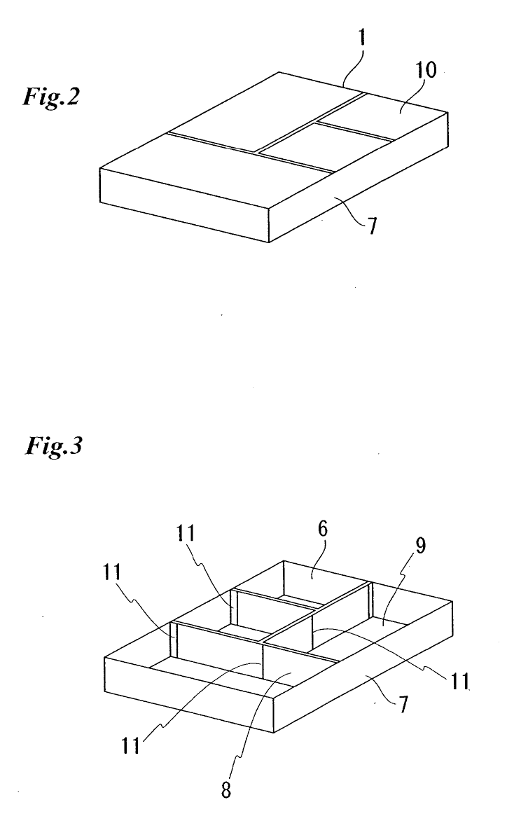

FIG. 2 is a perspective view of the shielding box in the state of the bottom wall facing up, and FIG. 3 is a perspective view of the shielding box in the state of the opening facing up. This shielding box 1, as shown in FIGS. 2 and 3, is nearly box-shaped and has bottom wall 10, side walls 7 formed to rise from the outer peripheries of the bottom wall 10, and opening 6 described by the edges of the side walls 7 opposite the bottom wall 10. The shielding box 1 may have partition walls 8 dividing its interior into a plurality of cells 9.

When securing the shielding box 1 and the wiring board, the shielding box 1 is pressed by the inner wall of the case, causing a portion of the shielding box 1 to elastically deform and the ends of the side walls 7 at the opening 6 side to make contact with the wiring board 2.

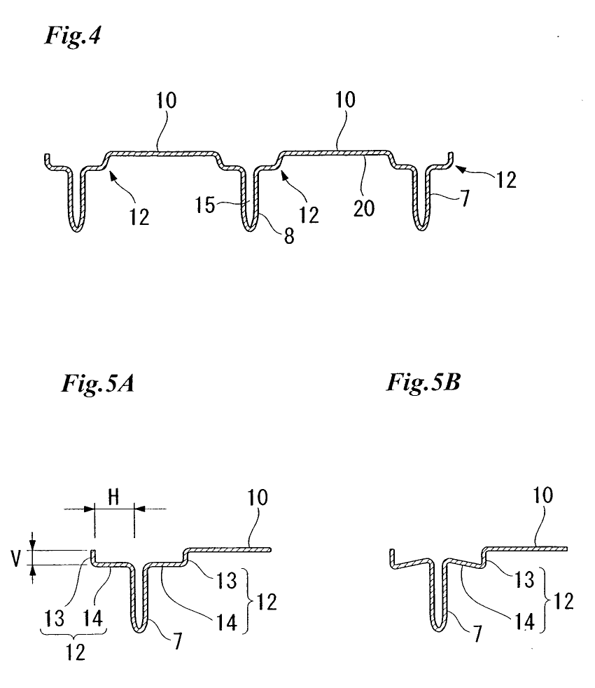

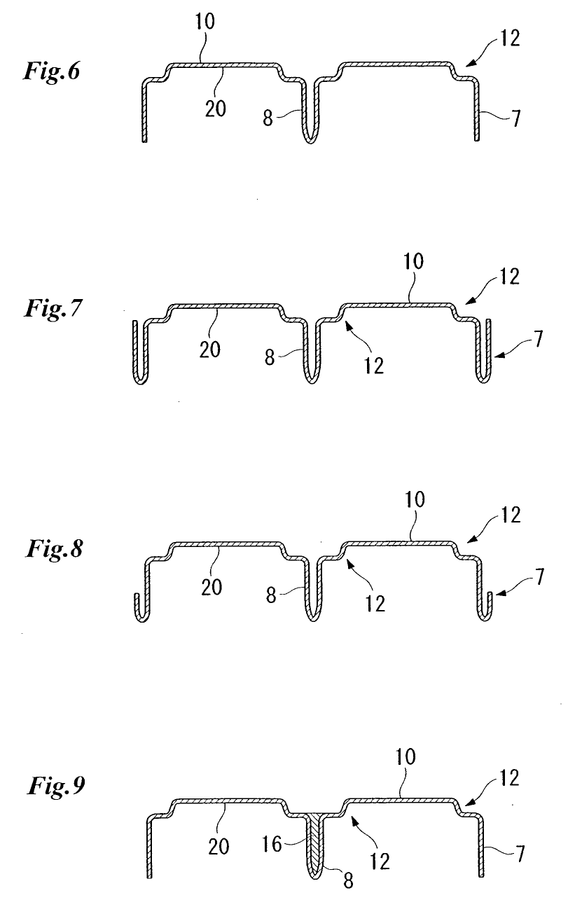

FIGS. 4 and 6 show embodiments of the shielding box 1 of which a portion is elastically deformed. In the embodiments of FIGS. 4 and 6, the side walls 7 and the partition walls 8 are connected to the bottom walls 10 through elastic connectors 12 formed to act as plate springs with respect to the bottom walls 10. The side walls 7 and the partition walls 8 are disposed in a position at which the ends of the side walls 7 and the partition walls 8 at the opening 6 side can be connected to the ground 4 when the shielding box 1 is pressed against the wiring board 2.

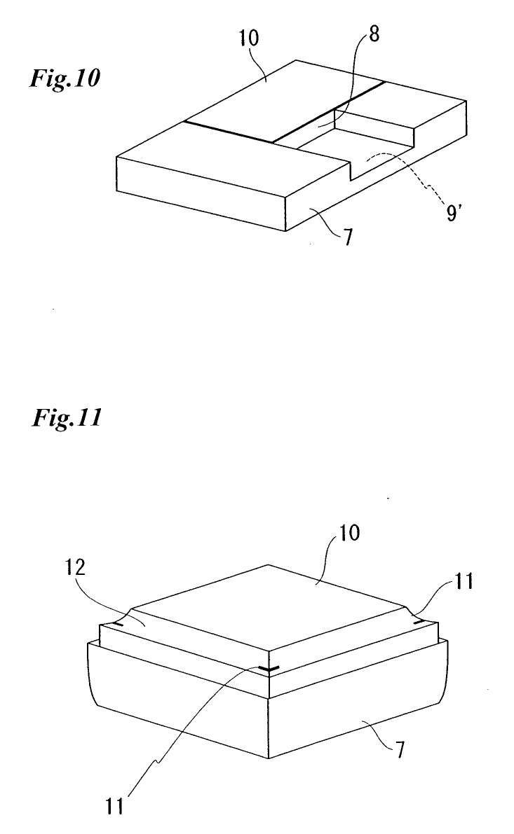

The size of the shielding box 1 is determined by the volume of housed electronic circuits 5, which have an overall side length of between 10 and 100 mm and height of 1 to 10 mm, although not limited to this. The cells 9 may all have the same height, or as shown in FIG. 10, the height of cell 9′ of a portion may differ.

The corner portion formed by two side walls 7 is rounded in the radial range of R 0.1 to 3 mm.

As shown in FIGS. 4 and 6, because the side walls 7 and the partition walls 8 are connected to the bottom walls 10 through the elastic connectors 12 formed to function as plate springs with respect to the bottom walls 10, the stress applied to the shielding box 1 is absorbed by the flexure of the elastic connectors 12, enabling the ends of the side walls 7 or the partitioning walls 8 to be brought into contact with the ground 4 by a small pressing force.

FIG. 5A shows an embodiment of the elastic connectors 12, while FIG. 5B shows the state of the elastic connectors 12 flexing under the pushing pressure applied to the bottom walls 10 of the shielding box 1.

The elastic connectors 12 may have any kind of structure provided it is a structure in which the elastic connectors 12 can elastically deform under pushing pressure applied to the bottom walls 10. However, as shown in the sectional views of FIGS. 5A and 5B, the structure preferably includes a rising portion 13 that rises once from the bottom wall 10 toward the opening and a horizontal portion 14 that extends in parallel to the bottom wall 10, connecting the end of the rising portion 13 opposite the bottom wall 10 and the end of the side wall 7 or the partition wall 8. By the flexible connectors 12 having such a structure, when stress acts on the bottom walls 10 of the shielding box 1, a part of the stress is absorbed by flexure of the horizontal portions 14, thereby preventing excessive stress from acting on the side walls 7 and the partition walls 8. When the pressing force is released, the elastic connectors revert to their original shape.

As shown in FIG. 5A, in order for the elastic connectors 12 to sufficiently function, it is better that the distance “H” of the horizontal portions 14 of the elastic connectors 12 be longer than the height “V” of the rising portions 13. The longer the distance of the horizontal portions 14 on the elastic connectors 12 (that is, the distance from the rising portions 13 to the side walls 7 or partition walls 8) the lower the load exerted by them. However, when stress acts on the shielding box 1, it is important that the horizontal portions do not come into contact with the electrical components included therein. “H” is preferably in the range of 0.5 to 5 mm. “V” of the rising portions 13 in the elastic connectors 12 is preferably greater than the amount of compressive displacement of the shielding box 1, being in the range of 0.2 to 4 mm.

As shown in FIGS. 7 and 8, making the side walls 7 a folded structure increases the rigidity of the opening end. Doing so can ensure its linearity, enabling suppression of deformation caused by compression, thereby achieving a firm connection to the ground 4 with no slippage. Even when only the inner surface of the shielding box 1 is subjected to electrical conductivity treatment, the conductive surface can be pressed against the ground 4.

If the end of the partition walls 8 is sharp, there is high contact stability. Alternatively, it may have molded dents or small projections at the ridge of the edge formed by pressing a blade or pin from above into the recess of the partition walls 8 shown in FIG. 4. However, the gaps formed between partition walls 8 and the ground 4, should, as shown below, have a relation to a wavelength.

Providing slits 11 at the bottom of the partition walls 8 to divide them into a plurality of pieces enables the plurality of pieces located between the slits 11 to move independently of each other. Doing so is preferable for increasing the stability of the connection. Even in the case where the slits 11 are provided, compressing the shielding box 1 only causes the partition walls 8 to move vertically, and never spread out by buckling to open a large gap. It is good to avoid as much as possible providing the slits 11 in connector portions of a partition wall 8 with an adjacent partition wall 8 or side wall 7 dividing a cell 9 that encloses circuits 5 where leakage of electromagnetic waves is not desired.

When slits 11 are provided, the size of the allowable gap is ½ or less, and preferably ¼ or less, the wavelength that should not be allowed to pass.

Compressing the bottom wall 10 causes distortion in the elastic connectors 12, preventing the smooth vertical movement of the side walls 7. As shown in FIG. 11, this problem can be solved by making hook-like slits 11 in each corner of the elastic connectors 12 of the shielding box 1 having folded side walls 7 but no partition walls 8, to enable independent movement of the elastic connector 12 of each side. In other words, the problem can be solved by making the elastic connector 12 of each side independent to prevent competition between them.

On the bottom wall 10, openings of an allowable size in relation to the wavelength may be provided for ventilation or weight reduction. In order to ensure insulation of the enclosed electronic components, the inner surface of the bottom wall 10 may be insulated by applying, for example, insulation tape thereon. For absorption of the generated electromagnetic waves, a layer containing a soft magnetic material, such as ferrite, chromium ferrite, and permalloy; carbon micro-coil; and diamond-like carbon may be used in conjunction.

Because the ends of the side walls 7 and the partition walls 8 are brought into contact with the ground 4 by a low pressing force caused by elastic deformation of the elastic connectors 12, in order to deform under a low load, the shear modulus of elasticity of the material of the shielding box 1 is preferably in a range of 10⁵ to 10⁹ Pa.

The thickness of the elastic connectors 12 is preferably 1 mm or less, and more preferably 0.05 to 0.5 mm depending on the shear modulus of elasticity. When the shear modulus of elasticity exceeds the range of 10⁵ to 10⁹ Pa, the shielding box 1 exerts an excessive load on the ground 4, causing deformation of the case 3 and 3′ and the wiring board 2 and resulting in defective contact. On the other hand, when the shear modulus of elasticity is less than this range, the shielding box 1 can no longer maintain its shape, which may cause it to short circuit by contact with the enclosed electronic components, and insufficient contact pressure also leads to defective contact.

The thickness of the side walls 7 and the partition walls 8 is preferably 1 mm or less and more preferably 0.2 to 0.8 mm. When the thickness exceeds 1 mm, space of that amount must be provided around the electronic circuits 5, thereby inhibiting compactness of the electronic device.

In the case of the side walls 7 and the partition walls 8 having folded structures as shown in FIGS. 7 and 8, this thickness refers to the total of the thickness of the two sheets resulting from the fold and the space therebetween.

In the case of the elastic connectors 12 having, as described above, a structure comprising the rising portions 13 and the horizontal portions 14, even if the elastic connectors 12 have the same thickness as the side walls 7 or the partition walls 8, the deformation of the elastic connectors 12 can absorb the stress resulting from a pressing force acting on the bottom wall 10 without deforming of the side walls 7 and the partition walls 8.

Metal or a material made of synthetic resins is chosen as the material constituting the shielding box 1, but synthetic resins are favored from the aspects of ease of processing and weight. These synthetic resins include thermoplastic resins such as polyethlene terephthalate, polystyrene, polycarbonate, polyacrylonitrile, polyamide, polyphenylene oxide, copolymer of acrylonitrile, butadiene and styrene, and a copolymer of ethylene and vinyl acetate, thermoplastic elastomers such as polyester elastomer, styrene elastomer, polyamide elastomer and polyurethane elastomer, and rubbers such as ethylene propylene rubber, styrene-butadiene rubber, nitrile rubber, polyurethane rubber, silicone rubber. In addition, alterations, mixtures and compounds of the above materials may be used.

Because materials other than metal are insulative, at least one surface of the material must be electrically conductive, with the surface resistance preferably being 10¹Ω/□to 10⁻²Ω/□. A sufficient shielding effect cannot be obtained when the resistance is higher than this. Physical deposition is a convenient method of conductivity treatment that can provide metal thin film 20 of low resistance with a dry process without pre-processing. Publicly known methods of physical deposition such as vapor deposition, (magnetron) sputtering, and ion plating can be adopted. The substrate is a synthetic resin molded body, so its heat resistance is not necessarily good, and problems of adherence with the cooling plate arise when cooling the back face, so it is vital to make a selection among the aforementioned methods keeping in mind processing time. It is preferable for this physical deposition to be performed after forming the shielding box because when deposition is performed after molding, there is no peeling of the deposited film 20 due to deformation.

In magnetron sputtering, the substrate is situated outside the plasma generated between a pair of targets in a facing target-type sputtering apparatus, so it receives no plasma impact. Because of this, the film growth speed is fast, and there is no unnecessary heating of the substrate. Therefore, magnetron sputtering has the characteristic of enabling conductivity treatment to be performed without impairing the dimensional accuracy of the molded body of the shielding box 1 made of synthetic resin, which is particularly preferable.

In a facing target-type sputtering apparatus, the substrate is situated outside the plasma, so the formed metal thin film 20 is not re-etched and there is no scattering or carrying off by argon gas, so the formed film has good properties, leading to the obtainment of a compact metal layer. Accordingly, even if the formed metal thin film 20 has the same thickness as those obtained in other methods, it has the advantages of a lower surface resistance and higher shielding effect.

Conductivity treatment methods other than physical deposition include a method of kneading a conductive filler such as a powdered metal or carbon black into a synthetic resin in advance, a method of applying conductivity by coating with a paint containing powdered metal or carbon black, a metal spraying method, and a plating method. In the conductive filler kneading method, while there are no restrictions on the shape of the conductive filler, those having a high aspect ratio are effective. Reflection of electromagnetic waves can be inhibited when the surface resistance is low, but in order to efficiently attenuate them, soft magnetic materials such as ferrite, chromium ferrite, and permalloy; and carbon micro-coil may be used in conjunction. In the conductive filler kneading method, raising the mix ratio of the powdered metal in order to obtain the desired surface resistance leads to an increase in the film thickness of the electrically conductive layer, which increases stiffness and may prevent the smooth operation of the elastic connectors 12.

In the conductive paint coating method, the paint easily comes off, which may cause short-circuiting in the enclosed electronics.

Metal spraying also poses the problems of increased rigidity and thermal deformation of thin synthetic resin occurring easily from metal spraying.

Forming a metal thin film by plating places restrictions on the synthetic resin material from the point of plating resistance and involves troublesome preparations such as pretreatment to improve contact and masking of areas where plating is not required, which slows the film growth speed, leading to low productivity. It also requires waste liquid treatment, which can hardly be described as good for the environment.

Such metals as silver, copper, gold, aluminum, nickel and alloys thereof having a low resistance are used in conductivity treatment, with copper, which has a fast deposition speed, being particularly preferable. Also, the shielding box 1 must be electrically connected to the ground 4 of the wiring board 2 and energized, so use of materials that easily lose their conductance due to oxidation and the like should be avoided. From this standpoint, it is preferable to provide nickel, which is comparatively resistive to oxidation, after copper deposition. Brass, which is an alloy of copper and zinc, is particularly preferable because it has low specific resistance, is resistant to oxidation and has a fast deposition speed.

The synthetic resin shielding box 1 can be molded into a box-like shape by publicly known methods using a sheet or pellets of the aforementioned material, and can be formed by die molding, vacuum molding, blow molding, injection molding and mold molding. Slits 11 may be formed in the die in advance, or may be provided in the molded shielding box 1 using a cutter.

In vacuum molding and blow molding, which boast fast molding cycles, molding is achieved by heating a thermoplastic film with a thickness of between 50 and 500 μm to 50 to 200° C. and subjecting it to a vacuum or pressure, respectively, so that it conforms to the shape of the die.

In the case of molding a sheet, as shown in FIGS. 4 to 8, partition walls 8 are formed by folding the sheet back on itself. When employing injection molding, as shown in FIG. 9, partition walls 8 can be formed in the shape of resin 16 injected therein.

When a sheet is employed, immediately after the molding step, conductivity treatment, cutout, inspection and trimming, etc. can be performed in the shape of a hoop, making conveyance easy. When injection molding is used, the thickness of the elastic connectors 12 can be altered, enabling the manufacture of a precision article.

The shielding box 1 is connected by contact with the ground 4 of the wiring board 2 inside separated case 3′ , so that by combining with the other separated case 3, it is connected by pressure applied from the inner surface of the case 3. The free height of the shielding box 1 (the height in the state of no stress being applied to the shielding box 1) after fitting the case together needs to be greater than the gap between the case 3 and the ground 4 of the wiring board 2, being preferably approximately 0.1 to 2 mm greater than this gap. If smaller than this, a sufficient amount of pressure displacement cannot be obtained by warpage, waviness or thickness unevenness of the cases 3 and 3′ or the wiring board 2. If greater than this, the deformation of the shielding box 1 increases, which may lead to the generation of excess load, which is not preferable for the connection.

In the shielding method using the shielding box of the present invention, the shielding box 1 is mounted on the wiring board 2 so as to envelope the electronic circuits 5 of the wiring board 2 housed inside the case 3′ . By fitting the case 3, the shielding box 1 is housed inside the case, and the bottom wall 10 of the shielding box 1 is pressed by the inner surface of the case 3 facing the wiring board 2, thereby pressing the shielding box 1 into contact with the wiring board 2.

The cases 3 and 3′ may be fitted together while the shielding box 1 is simply resting on the wiring board 2, but it may also be temporarily fixed with adhesive tape before fitting the cases 3 and 3′ . Also, when the partition walls 8 of the shielding box 1 are molded by folding the film back on itself, the shielding box 1 may also be temporarily fixed by fitting reinforcing ribs of the cases 3 and 3′ into pockets 15 of the partition walls 8.

When the shielding box 1 is pressed against the wiring board 2, a portion of the shielding box 1, namely the elastic connectors 12 between the side walls 7 and/or the partition walls 8 and the bottom walls 10 in the embodiments of FIGS. 6 to 8, undergoes elastic deformation. This brings the ends of the side walls 7 and/or partition walls 8 into contact with the ground 4 of the wiring board 2. Electromagnetic wave shielding is effected by covering the electronic circuits 5 on the wiring board 2 by the shielding box 1 so that the electronic circuits 5 on the wiring board 2 are enveloped by the shielding box 1 and metal foil on another layer of the wiring board 2.

In the embodiments of FIGS. 4 to 9, the metal thin film 20 is formed all over the inner surface of the shielding box 1, but it may also be formed on only the outer surface or both the inner and outer surfaces thereof.

### EXPERIMENTAL EXAMPLES

The present invention is explained in further detail using the experimental examples below, but the invention is not to be considered as being limited by these experimental examples.

### Experimental Example 1

A sample for evaluating the surface resistance and electromagnetic wave shielding effect was fabricated by providing an 80 nm thick copper thin film on a high impact polystyrene sheet (0.25 nm thickness, containing dry silica at an amount of 0.1 percent by weight) by ion plating, and then providing a 26 nm nickel thin film thereon.

### Experimental Example 2

An evaluation sample was fabricated by providing a thin film similar to that of the experimental example 1 on a high impact polystyrene sheet similar to that used in the experimental example 1 by sputtering with a facing target-type sputtering apparatus (Mirrortron sputter apparatus).

### Experimental Example 3

An evaluation similar to that of the experimental example 2 was fabricated, except that instead of copper and nickel a brass thin film with a thickness of 106 nm was provided in one stage using brass.

### Comparative Example 1

An evaluation sample was obtained by spraying an acrylic coat containing powdered silver and powdered copper (at a mass ratio of 82.3 percent by weight of the metal in the solid content, with a silver to copper ratio of 3:7) on the polystyrene sheet used in the experimental example 1 until the same surface resistance in the experimental example 1 was obtained.

### Comparative Example 2

After roughening the polystyrene sheet used in experimental example 1 with chromic acid and washing with hydrochloric acid, a catalyst comprising a platinum/tin complex was adsorbed thereto to dissolve the tin salt. It was then immersed in an electroless nickel plating solution including phosphor to deposit nickel. Nickel was then formed by electroplating to provide a nickel layer with a thickness of 0.4 μm.

(Evaluation)

The surface resistance of the obtained sample was measured using a Loresta GP resistivity meter (four-terminal method) made by Dia Instruments Co., Ltd. Measurement of the electromagnetic wave shielding effect was performed using the TM wave shield measurement method (measurement frequency: 100 MHz to 5 GHz). The results are shown in Table 1. A coefficient for evaluating the film quality is shown by the value multiplied the product of film thickness (nm) and surface resistance (Ω/□).

TABLE 1

| | Experimental | Experimental | Experimental | Comparative | Comparative |
|---|---|---|---|---|---|
| | example 1 | example 2 | example 3 | example 1 | example 2 |
| Method | Ion plating | Mirrortron | Mirrortron | Coating | Plating |
| | | sputtering | sputtering | | |
| Metal | Nickel/copper | Nickel/copper | Brass | Silver/copper | Nickel |
| Film | 26/80 | 26/80 | 106 | 31,500 | 400 (partial) |
| thickness | | | | | |
| (nm) | | | | | |
| Surface | 1.6 | 0.53 | 0.48 | 1.6 | Cannot be |
| resistance | | | | | measured |
| (Ω/□) | | | | | |
| Film | 170 | 56 | 51 | 50,400 | Cannot be |
| thickness × surface | | | | | measured |
| resistance | | | | | |
| Attenuation | 38 | 46 | 48 | 38 | Cannot be |
| factor (db) | | | | | measured |
| (0.5 GHz) | | | | | |
| Attenuation | 38 | 46 | 48 | 38 | Cannot be |
| factor (db) | | | | | measured |
| (3 GHz) | | | | | |
| Film | 55/55 | 40/40 | 54 | — | — |
| formation | | | | | |
| time (s) | | | | | |
| Remarks | | Short film | Short film | Rough | Uneven |
| | | formation | formation | surface | formation |
| | | time | time | Powder loss | Poor |
| | | Good film | Low | Rigid, lack of | adhesion |
| | | quality | resistance | flexibility | Does not |
| | | | Good film | | function as a |
| | | | quality | | sample |
| Overall | ◯ | ◯ | ◯ | X | X |
| evaluation | | | | | |

### Experimental Example 4

A shielding box was molded having a rectangular bottom surface as shown in FIG. 11 by pneumatic molding of a high impact polystyrene sheet (thickness 0.25 mm; containing carbon black at an amount of 1.2 percent by weight). The box externally measures 60 mm long×49 mm wide×2 mm high. The elastic connectors measure H=0.6 mm, V=0.4 mm on the long side; and H=0.8 mm, V=0.4 mm on the short side. Sputtering is applied to the inner surface of this molded body with a facing target-type sputtering apparatus to form a brass thin film with a thickness of 51 nm. The folded portion of the outer wall is cut 1 mm from the contact portion, resulting in a shielding box.

The surface resistance of the bottom portion of the interior was 1.5 Ω/□ when measured in the same way as aforementioned, giving a film quality evaluation coefficient of 77.

The shielding box was mounted bottom up on a gold plated substrate, compressing the bottom walls as a whole to deform the elastic connectors by 0.2 mm, whereupon the contact resistance between the substrate and the connectors (circumferential length of approximately 200 mm) was measured. Good resistance averaging 170 mΩ/10 mm was found with a load of 86 g per 10 mm.

### INDUSTRIAL APPLICABILITY

The shielding box of the present application can effect electromagnetic wave shielding simply by mounting on a wiring board and combining as is with a case, thereby allowing convenient connection of the shielding box and definite shielding of electromagnetic waves. The shielding box is also easily formed. Only a small amount of stress is applied to the shielding box for electromagnetic wave shielding, and so excessive force is not exerted on the wiring board. Because the metal thin film is compact, it requires no excessive thickness and there is no deformation of the elastic connectors, and so no excessive stress is applied to the wiring board during electromagnetic wave shielding. This shielding box could therefore make a significant contribution to the development of the electronics industry.

The shielding method of the present invention achieves convenient and certain electromagnetic wave shielding of electronic circuits simply by mounting a shielding box on a wiring board so as to enclose various electronic circuits on the wiring board stored in a case and combining with a case. The shielding method could therefore make a significant contribution to the development of the electronics industry.

1. A shielding box comprising a molded body having a box shape, the molded body comprising:
a bottom wall;
side walls formed to rise from the outer peripheries of the bottom wall; and
an opening described by the edges of the side walls opposite the bottom wall,
the side walls being connected to the bottom wall through elastic connectors formed to act as plate springs with respect to the bottom wall, and at least one of the inner surface and outer surface of the molded body being electrically conductive.

2. A shielding box for blocking electromagnetic waves that is housed in a case and covers electronic circuits on a wiring board, the shielding box comprising a molded body having a box shape, the molded body comprising:
a bottom wall;
side walls formed to rise from the outer peripheries of the bottom wall; and
an opening described by the edges of the side walls opposite the bottom wall;
at least one of the inner surface and outer surface of the molded body having a metal thin film formed by physical deposition; and the ends of the side walls at the opening side making contact with the wiring board while a portion of the shielding box being pressed by an inner wall of the case elastically deforms when securing the shielding box and the wiring board.

3. The shielding box according to claim 1, having partition walls dividing its interior into a plurality of cells, the partition walls connected to the bottom wall through elastic connectors formed to act as plate springs with respect to the bottom wall.

4. The shielding box according to claim 1, wherein the shear modulus of elasticity of the material constituting the molded body ranges from 10⁵ to 10⁹ Pa.

5. The shielding box according to claim 1, wherein the elastic connectors comprise a rising portion that rises once from the bottom wall toward the opening and a horizontal portion that extends in parallel to the bottom wall, connecting the end of the rising portion opposite the bottom wall and the opposite end of the side wall or the partition wall.

6. The shielding box according to claim 5, wherein when the distance of the horizontal portions of the elastic connectors is H and the height of the rising portions is V, H>V.

7. The shielding box according to claim 1, wherein the thickness of the side walls and/or the partition walls is 1 mm or less.

8. The shielding box according to claim 1, wherein the surface resistance of at least one of the inner surface and the outer surface of the molded body ranges from 10¹ to 10⁻²Ω/□.

9. The shielding box according to claim 1, wherein the partition walls are divided into a plurality of pieces by slits.

10. The shielding box according to claim 1, wherein the molded body is formed by molding from one sheet of material.

11. The shielding box according to claim 1, wherein the free height of the shielding box is larger than a gap formed between the inner surface of the case and the wiring board facing each other, the gap being in the space surrounded by the case in which the shielding box is housed and the wiring board.

12. The shielding box according to claim 2, wherein the side walls are connected to the bottom wall through elastic connectors formed to function as plate springs with respect to the bottom wall.

13. The shielding box according to claim 2, wherein the metal thin film from physical deposition is formed by using a facing target-type sputtering apparatus.

14. The shielding box according to claim 2, wherein the surface resistance of at least one of the inner surface and the outer surface of the molded body ranges from 10¹ to 10⁻²Ω/□, and the relationship between the thickness T (nm) and the surface resistance R (Ω/□) of the metal thin film satisfies the condition T×R<200 in a range of 20<T<200.

15. The shielding box according to claim 2, wherein the metal thin film is made from a plurality of metals.

16. The shielding box according to claim 2, wherein the metal thin film is a brass thin film.

17. A shielding method of electromagnetic wave shielding comprising the steps of:
providing a shielding box comprising a molded body having a box shape, the molded body comprising:
a bottom wall;
side walls formed to rise from the outer peripheries of the bottom wall; and
an opening described by the edges of the side walls opposite the bottom wall,
the side walls being connected to the bottom wall through elastic connectors formed to act as plate springs with respect to the bottom wall, and at least one of the inner surface and outer surface of the molded body being electrically conductive:
providing a shielding box in a case having a wiring board stored therein;
pressing the bottom wall of the shielding box by the inner surface of the case opposing the wiring board so as to press the ends of the side walls and/or partition walls against the wiring board while elastically deforming the elastic connectors; and
covering electronic circuits on the wiring board with the shielding box.

18. The shielding box according to claim 2, having partition walls dividing its interior into a plurality of cells, the partition walls connected to the bottom wall through elastic connectors formed to act as plate springs with respect to the bottom wall.

19. The shielding box according to claim 2, wherein the surface resistance of at least one of the inner surface and the outer surface of the molded body ranges from 10¹ to 10⁻²Ω/□.

20. A shielding method of electromagnetic wave shielding comprising the steps of:
providing a shielding box for blocking electromagnetic waves that is housed in a case and covers electronic circuits on a wiring board, the shielding box comprising a molded body having a box shape, the molded body comprising:
a bottom wall;
side walls formed to rise from the outer peripheries of the bottom wall; and
an opening described by the edges of the side walls opposite the bottom wall;
at least one of the inner surface and outer surface of the molded body having a metal thin film formed by physical deposition; and the ends of the side walls at the opening side making contact with the wiring board while a portion of the shielding box being pressed by an inner wall of the case elastically deforms when securing the shielding box and the wiring board;
providing a shielding box in a case having a wiring board stored therein;
pressing the bottom wall of the shielding box by the inner surface of the case opposing the wiring board so as to press the ends of the side walls and/or partition walls against the wiring board while elastically deforming the elastic connectors; and
covering electronic circuits on the wiring board with the shielding box.
